(19) United States
(12) Patent Application Publication
(10) Pub. No.: US 2011/0008568 A1
(43) Pub. Date: Jan. 13, 2011

(54) Oriented noble metal single crystalline nanowire and preparation method thereof

(76) Inventors: Bongsoo Kim, Daejeon (KR); Yeongdong Yoo, Daejeon (KR)

Correspondence Address: THE NATH LAW GROUP, 112 South West Street, Alexandria, VA, 22314, US

(21) Appl. No.: 12/289,762

(22) Filed: Nov. 3, 2008

(51) Int. Cl. B32B 7/00; B32B 15/04; C30B 25/18; C22C 5/00; C22C 5/02; C22C 5/04

(52) U.S. Cl. 428/98; 428/469; 117/88; 420/591; 420/507; 420/463

(57) ABSTRACT

Disclosed are a noble metal nanowire oriented to a surface of a single crystalline substrate, which is prepared using a noble metal oxide, noble metal or noble metal halide as a precursor and, in addition, a method for preparation of the same. The present invention adopting a vapor phase transport method to prepare the noble metal nanowire without any catalyst has advantages of simplifying and reproducing processes of the method and enabling mass production thereof. The prepared nanowire exhibits high purity and quality and a complete crystalline state without defects and/or impurities. The prepared noble metal nanowire also has orientation to a surface of a single crystalline substrate and alignment of the nanowire as well as the orientation can be controlled.

### BACKGROUND OF THE INVENTION

This application claims priority to Korean Patent Application No. 2008-0036360, filed on Apr. 18, 2008, in the Korean Intellectual Property Office, the entire contents of which are hereby incorporated by reference.

1. Field of the Invention

The present invention relates to noble metal nanowires with orientation to a surface of a single crystalline substrate and a method for preparation thereof using a noble metal oxide, a noble metal or a noble metal halide as a precursor through a vapor phase transport process.

2. Description of the Related Art

Noble metal single crystalline nanowires are generally known to have superior chemical stability and excellent thermal conductivity and electric conductivity so that they can be preferably used in various applications including electric, magnetic and optical devices and sensors.

For instance, gold (Au) has high electric and thermal conductivity and favorable optical properties sufficient to exhibit high Surface Enhanced Raman scattering (SERS) in a visible light spectrum. Au may be used to prepare a nanowire, which in turn, is expected to play a role in advanced development of various fields such as micro-electronic devices, optical sensors and so forth. Especially, since a signal intensity greatly depends on detailed forms of Au nanostructure in SERS, an improved process for preparation of a nanowire having a clean surface according to an exact definition and analysis is absolutely required so as to preferably manufacture desired chemical or bio sensors.

As for a metal nanostructure, molecules are generally adsorbed to a surface of the nanostructure by a self-assembled monolayer (SAM). That is, a SAM may be used to prepare an Au nanostructure with a molecular layer uniformly adsorbed on a surface thereof. The Au nanowire and a SAM may be used to observe SERS phenomenon of molecules while a molecule consisted of the SAM may be used as a linker. As a result, these are preferably applied in selective bio-molecular analysis and optical devices.

In another instance, Pd is drawing attention in regard to application thereof in manufacturing sensors. With improvement of advanced science and technologies, there is a strong requirement for development of various precision sensors necessary for high precision applications. However, development of high sensitivity sensors is still a long way off in domestic fields and even outside the country. Especially, it is important to develop a novel hydrogen gas sensor useful for a high sensitivity fuel cell, which is capable of detecting leakage of hydrogen occurring when the fuel cell is developed, manufactured and/or commonly used, while simultaneously executing studies and investigation for fuel cells as a future clean energy source. With development of such a hydrogen sensor, novel and improved materials used to manufacture the hydrogen sensor are also required. Pd metals are attracting more interest among these materials. Since Pd metals have strong hydrogen adsorption and can absorb hydrogen up to about 900 times their volume, a great deal of studies in regard to nanowire synthesis using Pd metals and application thereof in high sensitive sensors are now in progress by domestic and foreign research and development teams.

As described above, although noble metal nanowires are highly useful for electric, magnetic and/or optical devices, sensors, etc., synthesis of a noble metal nanowire without the use of any catalyst under vapor phase conditions has not been reported. Conventional methods for synthesis of a noble metal nanowire are mostly known as liquid phase chemical methods using a cast, a surfactant and/or a capping agent, etc. Therefore, an approach for manufacturing a noble metal nanowire under vapor phase conditions without use of a catalyst has not yet proposed.

Such a liquid phase chemical method has difficulty in altering shapes of a noble metal nanowire, exhibits reduced purity thereof, and has a drawback that the nanowire has defects and/or becomes polycrystalline. In addition, the liquid phase chemical method has a problem in mass production of noble metal nanowires due to complicated processes thereof.

Technical problems regarding improvement of device performance even with decrease in size of a device bring up a demand for fundamental research into synthesis of nanowires and characteristics of the same. Such a nanowire is typically prepared by a bottom-up type synthesis, which generally leads to growth of the nanowire at disordered positions and in disordered directions. The disorderedly grown nanowire may be an obstacle to practical applications of the nanowire. Accordingly, in order to embody a large sized device, a novel process for preparation of a nanowire with excellent precision control of positions and directions of the nanowire must first be attained.

The present inventors have proposed a method for mass-production of a high quality and purity noble metal nanowire and, after extensive research and studies regarding the same, suggested that precision controlled growth of a noble metal nanowire may enable a variation in positions and/or directions of the nanowire. An oriented noble metal nanowire aligned on a substrate can become a foundation to embody a three-dimensional device.

In addition, if transition metals such as Co, Fe, Mn, etc. are doped in a trace amount on a vertically grown noble metal nanowire, the nanowire commonly exhibits ferromagnetic properties. Consequently, a process for vertical growth of a nanowire according to the present invention may afford basic technologies, which are very important for manufacturing three-dimensional memories.

### SUMMARY OF THE INVENTION

Accordingly, the present invention has been proposed to solve problems of conventional techniques described above, and an object of the present invention is to provide a high quality and purity noble metal single crystalline nanowire with orientation to a substrate, which is prepared by a vapor phase transport process without using a catalyst and, in addition, a method for preparation thereof.

Another object of the present invention is to provide a device or sensor having the noble metal single crystalline nanowire described above.

A noble metal single crystalline nanowire according to the present invention may be prepared using a noble metal oxide, noble metal or noble metal halide as a precursor without using any catalyst, which is oriented to a surface of a semiconductor or nonconductive single crystalline substrate.

Orientation means that a nanowire formed on top of a substrate is oriented to a surface of the substrate in a direction relative to a long axis of the nanowire, which generally has a vertical or horizontal orientation to the surface of the substrate.

Such a noble metal single crystalline nanowire is prepared by heat treatment of a precursor placed in a front part of a reaction furnace and a single crystalline substrate placed in a rear part of the reaction furnace at a certain pressure in inert gas atmosphere. The orientation is controlled by kinds of the precursor, types of the single crystalline substrate, surface direction of the single crystalline substrate, heating temperature, flow rate of the inert gas, pressure, and combinations of two or more thereof.

In order to prepare an oriented noble metal nanowire in a specific direction to a surface of a substrate, a precursor is preferably maintained at 1,000 to 1,200° C. while maintaining a single crystalline substrate at 800 to 1,100° C. While flowing the inert gas at a flow rate of 50 to 200 sccm from the front part (on which the precursor is placed) to the rear part (on which the substrate is placed) of the reaction furnace, the heat treatment is preferably performed under a pressure of 3 to 20 torr.

Herein, the precursor may include noble metal oxide, noble metal and/or noble metal halide and a noble metal single crystalline nanowire may be prepared using the precursor. Preferred examples of the noble metal oxide may include gold oxide, silver oxide, palladium oxide, platinum oxide, iridium oxide, osmium oxide, rhodium oxide, ruthenium oxide and the like. An Au, Ag, Pd, Pt, Ir, Os, Rh or Ru single crystalline nanowire may be prepared using the noble metal oxide. Preferred examples of the noble metal may include Au, Ag, Pd, Pt, Ir, Os, Rh, Ru and the like. Preferred examples of the noble metal halide may be selected from noble metal fluoride, noble metal chloride, noble metal bromide and noble metal iodide, preferably noble metal chloride, noble metal bromide or noble metal iodide, and more preferably noble metal chloride. Such a noble metal halide may have at least one noble metal selected from Au, Ag, Pd, Pt, Ir, Os, Rh and Ru. The noble metal halide may further include a hydrated noble metal halide.

The precursor is preferably a noble metal oxide or noble metal.

The noble metal oxide is preferably selected from Au₂O₃ or PdO, the noble metal is preferably selected from Au or Pd, and the noble metal halide is preferably selected from gold halide or palladium halide.

The noble metal single crystalline nanowire has a specific crystalline structure substantially the same as bulk noble metal, with high purity and high crystallinity properties. A number of noble metal single crystalline nanowires may not be randomly but instead specifically aligned on a substrate.

The noble metal single crystalline nanowire may be vertically grown to a surface of a single crystalline substrate.

The noble metal single crystalline nanowire with vertical orientation may have the same crystalline structure as bulk noble metal and faceted shapes. In this regard, the faceted shape means that a surface of a nanowire is prepared not perfectly with regard to all faces of a crystal and, a tangent line has a discontinuously varied gradient on an outer circumference of the noble metal nanowire with a short or long axial cross-section.

The vertically grown noble metal single crystalline nanowire may be an Au single crystalline nanowire, the Au single crystalline nanowire may have a face centered cubic (FCC) structure. The Au single crystalline nanowire may have a faceted shape and a tangential gradient discontinuously varied on an outer circumference of the nanowire with a long axial cross-section. The Au single crystalline nanowire has a growth direction <110>. Accordingly, such <110> of the Au single crystalline nanowire is vertical to a surface of the substrate, and preferably vertical to a surface of a sapphire single crystalline substrate {0001}.

The vertically grown noble metal single crystalline nanowire is a Pd single crystalline nanowire and the Pd single crystalline nanowire may have a face centered cubic structure. The Pd single crystalline nanowire may have a faceted shape and a tangential gradient discontinuously varied on an outer circumference of the Pd single crystalline nanowire with a long axial cross-section. Preferably, the Pd single crystalline nanowire has a growth direction <110>. Such <110> of the Pd single crystalline nanowire is preferably vertical to a surface of the substrate, and preferably vertical to a surface of a sapphire single crystalline substrate {0001}.

In order to prepare a noble metal nanowire with vertical orientation to a surface of a substrate, a precursor is preferably maintained at 1,000 to 1,200° C. while maintaining a single crystalline substrate at 850 to 1,100° C. The heat treatment is preferably performed under a pressure of 3 to 8 torr while inert gas flows at a flow rate of 50 to 200 sccm from the front part to the rear part of the reaction furnace.

The noble metal single crystalline nanowire may be horizontally grown parallel to a surface of a single crystalline substrate.

The horizontally grown noble metal single crystalline nanowire may be an Au single crystalline nanowire and the Au single crystalline nanowire may have an FCC(Face Centered Cubic) structure. A face {110} or {111} of the Au nanowire may be parallel to the surface of the substrate.

The single crystalline substrate may be a sapphire substrate having a surface {0001}, which preferably has an orientation parallel to the face {110} of the Au nanowire.

The single crystalline substrate may be a sapphire substrate having a surface {11-20}, which preferably has an orientation parallel to the face {111} of the Au nanowire.

The horizontally grown noble metal single crystalline nanowire may be a Pd single crystalline nanowire and the Pd single crystalline nanowire may have an FCC structure. The single crystalline substrate on which the Pd single crystalline nanowire is formed may be a sapphire substrate having a surface {0001}.

In order to prepare a noble metal nanowire with horizontal orientation to a surface of a substrate, a precursor is preferably maintained at 1,000 to 1,200° C. while maintaining a single crystalline substrate at 800 to 950° C. The heat treatment is preferably performed under a pressure of 15 to 20 torr while inert gas flows at a flow rate of 50 to 200 sccm from the front part to the rear part of the reaction furnace.

The single crystalline substrate may include, for example, at least one selected from a group consisting of a Group 4 element single crystalline substrate, a Group 3-5 element single crystalline substrate, a Group 2-6 element single crystalline substrate, a Group 4-6 element single crystalline substrate, a sapphire single crystalline substrate, a silicon oxide single crystalline substrate, and a laminate of two or more thereof. A sapphire single crystalline substrate is particularly preferred.

A method for preparation of a noble metal single crystalline nanowire according to the present invention comprises heat treatment of a precursor containing a noble metal oxide, noble metal or noble metal halide, which is placed in a front part of a reaction furnace, as well as a semiconductor or nonconductive single crystalline substrate placed in a rear part of the reaction furnace at a certain pressure in inert gas atmosphere, so as to produce a noble metal single crystalline nanowire oriented to a surface of the single crystalline substrate.

Orientation means that a nanowire formed on top of a substrate is oriented to a surface of the substrate in a direction relative to a long axis of the nanowire, which generally has a vertical or horizontal orientation to the surface of the substrate.

As to the method of the present invention, the orientation is controlled by kinds of the precursor, types of the single crystalline substrate, surface direction of the substrate, heating temperature, flow rate of the inert gas, pressure, and combinations of two or more thereof.

Such a precursor may include noble metal oxides, noble metals or noble metal halides. A noble metal single crystalline nanowire may be prepared using the precursor. Preferred examples of the noble metal oxide may include gold oxide, silver oxide, palladium oxide, platinum oxide, iridium oxide, osmium oxide, rhodium oxide, ruthenium oxide and the like. An Au, Ag, Pd, Pt, Ir, Os, Rh or Ru single crystalline nanowire may be prepared using the noble metal oxide. Preferred examples of the noble metal may include Au, Ag, Pd, Pt, Ir, Os, Rh, Ru and the like. Preferred examples of the noble metal halide may be selected from noble metal fluoride, noble metal chloride, noble metal bromide and noble metal iodide, preferably noble metal chloride, noble metal bromide or noble metal iodide, and more preferably noble metal chloride. Such a noble metal halide may have at least one noble metal selected from Au, Ag, Pd, Pt, Ir, Os, Rh and Ru. The noble metal halide may further include a hydrated noble metal halide.

The precursor is preferably noble metal oxide or noble metal.

The noble metal oxide is preferably selected from Au₂O₃ or PdO, the noble metal is preferably selected from Au or Pd, and the noble metal halide is preferably selected from gold halide or palladium halide.

The single crystalline substrate may include, for example, at least one selected from a group consisting of a Group 4 element single crystalline substrate, a Group 3-5 element single crystalline substrate, a Group 2-6 element single crystalline substrate, a Group 4-6 element single crystalline substrate, a sapphire single crystalline substrate, a silicon oxide single crystalline substrate, and a laminate of two or more thereof. A sapphire single crystalline substrate is particularly preferred.

According to the method of the present invention, the noble metal single crystalline nanowire may be grown in a direction vertical to the surface of the single crystalline substrate. In this regard, a precursor is preferably maintained at 1,000 to 1,200° C. while maintaining a single crystalline substrate at 850 to 1,100° C. The heat treatment is preferably performed under a pressure of 3 to 8 torr while inert gas flows at a flow rate of 50 to 200 sccm from the front part to the rear part of the reaction furnace. The single crystalline substrate on which the vertically growing noble metal single crystalline nanowire is prepared may preferably be a sapphire single crystalline substrate having a face {0001}.

The precursor may be Au₂O₃ or Au and the vertically grown nanowire may be an Au single crystalline nanowire.

Alternatively, the precursor may be PdO or Pd, while the vertically grown nanowire may be a Pd single crystalline nanowire.

As to the method of the present invention, the noble metal single crystalline nanowire may be grown in a direction parallel to the surface of the single crystalline substrate. In this regard, a precursor is preferably maintained at 1,000 to 1,200° C. while maintaining a single crystalline substrate at 800 to 950° C. The heat treatment is preferably performed under a pressure of 15 to 20 torr while inert gas flows at a flow rate of 50 to 200 sccm from the front part to the rear part of the reaction furnace.

The single crystalline substrate on which the horizontally grown noble metal single crystalline nanowire is prepared may be preferably a sapphire single crystalline substrate and this substrate may have a surface {0001} or {11-20}.

The precursor may be Au₂O₃ or Au and the horizontally grown nanowire may be an Au single crystalline nanowire.

Alternatively, the precursor may be PdO or Pd, while the horizontally grown nanowire may be a Pd single crystalline nanowire.

The noble metal single crystalline nanowire prepared by the inventive method may be used in an electric, optical or magnetic device, a memory device or a micro-electro-mechanical systems (MEMS) structure.

The noble metal single crystalline nanowire of the present invention may be used in an electric, optical or magnetic device, a memory device or a MEMS structure.

The method of the present invention adopts a vapor phase transport method without using any catalyst to prepare a noble metal nanowire, so that it can simplify and allow easy reproduction of processes thereof and have merits in mass production. The prepared noble metal nanowire exhibits high crystallinity and formable properties as well as high purity and has a single crystalline structure. In addition, the noble metal nanowire has a specific orientation to a surface of a single crystalline substrate.

The present invention may control and reproduce a specific orientation of the noble metal nanowire to the surface of the substrate. The present invention may provide an opportunity for studies in regard to physical, optical and/or electro-magnetic properties of the noble metal nanowire by a simple preparation process for mass-production thereof. More particularly, the present invention may provide high purity and quality Au and/or Pd nanowires prepared using metals with excellent electric and thermal conductivities and chemical stability so that these nanowires can be utilized in manufacturing electric, optical and/or magnetic devices with high sensitivity and efficiency. Especially, a noble metal nanowire with orientation to the surface of the substrate may be preferably applied to three dimensional MEMS structures or three-dimensional memory devices.

### BRIEF DESCRIPTION OF THE DRAWINGS

These and other objects, features, aspects, and advantages of the present invention will be more fully described in the following detailed description of preferred embodiments, taken in conjunction with the accompanying drawings. In the drawings:

FIGS. 1A and 1B are a scanning electron microscope (SEM) picture illustrating an Au single crystalline nanowire prepared according to Example 1 of the present invention;

FIG. 2 is a graphical representation illustrating an X-ray diffraction (XRD) result of the Au single crystalline nanowire prepared according to Example 1 of the present invention;

FIGS. 3A to 3C are a transmission electron microscope (TEM) picture illustrating the Au single crystalline nanowire prepared according to Example 1 of the present invention;

FIG. 3A illustrates a limited visual field diffraction result of an Au single crystalline nanowire illustrated in FIG. 3(b);

FIG. 3B illustrates a dark field image of the Au single crystalline nanowire;

FIG. 3C is a high resolution TEM (HRTEM) picture of an Au single crystalline nanowire illustrated in FIG. 3(b);

FIG. 4 is a graphical representation illustrating an energy dispersive X-ray spectroscopy (EDS) result of the Au single crystalline nanowire prepared according to Example 1 of the present invention;

FIGS. 5A and 5B are a SEM picture showing a Pd single crystalline nanowire prepared according to Example 2 of the present invention;

FIG. 6 is a graphical representation illustrating an XRD result of the Pd single crystalline nanowire prepared according to Example 2 of the present invention;

FIGS. 7A to 7C are a TEM picture showing the Pd single crystalline nanowire prepared according to Example 2 of the present invention;

FIG. 7A illustrates a limited visual field diffraction result of a Pd single crystalline nanowire illustrated in FIG. 7B;

FIG. 7B illustrates a dark field image of the Pd single crystalline nanowire;

FIG. 7C is an HRTEM picture of a Pd single crystalline nanowire illustrated in FIG. 7B;

FIG. 8 is a graphical representation illustrating an EDS result of the Pd single crystalline nanowire prepared according to Example 2 of the present invention;

FIG. 9 is a SEM picture showing an Au single crystalline nanowire prepared according to Example 3 of the present invention;

FIGS. 10A and 10B are an HRTEM picture showing a barrier between the Au single crystalline nanowire prepared according to Example 3 of the present invention and a substrate;

FIG. 11 is a SEM picture showing an Au single crystalline nanowire prepared according to Example 4 of the present invention;

FIGS. 12A and 12B are an HRTEM picture showing a barrier between the Au single crystalline nanowire prepared according to Example 4 of the present invention and a substrate; and

FIG. 13 is a SEM picture showing a Pd single crystalline nanowire prepared according to Example 5 of the present invention.

### DETAILED DESCRIPTION OF THE INVENTION

Hereinafter, a noble metal single crystalline nanowire and a method for preparation thereof according to the present invention will be described in greater detail with reference to the accompanying drawings, which are given for the purpose of illustration to those skilled in the art and not to be construed as limiting the scope of the invention. Accordingly, other modifications or variations of the present invention may be embodied without limitation to embodiments illustrated by the drawings, wherein like reference numbers refer to like elements throughout.

Scientific and technical terms incorporated herein may have the same meanings as commonly known to those skilled in the art unless they are alternatively defined. In the following disclosure and drawings, a detailed description of functions and/or configurations will be omitted when it may make the subject matter of the present invention rather unclear.

A method for preparation of a noble metal nanowire oriented to a substrate according to the present invention comprises: heat treatment of a precursor containing a noble metal oxide, noble metal or noble metal halide, which is placed in a front part of a reaction furnace, as well as a semiconductor or nonconductive single crystalline substrate placed in a rear part of the reaction furnace at a certain pressure in inert gas atmosphere, so as to produce the noble metal single crystalline nanowires oriented to a surface of the single crystalline substrate.

Particularly, the precursor is vaporized by the heat treatment and transported by the inert gas and enables nucleation and growth of a noble metal material on the surface of the single crystalline substrate. As a result, the noble metal single crystalline nanowire which has vertical or horizontal orientation to the surface of the single crystalline substrate is prepared.

The method of the present invention uses only a noble metal oxide, noble metal or noble metal halide as a precursor without using any catalyst so as to form a noble metal nanowire on a single crystalline substrate. Since the noble metal single crystalline nanowire is prepared via a material transfer path in a vapor phase, the inventive method is simple and reproducible and allows production of high purity nanowire containing less impurities.

Additionally, the method of the present invention regulates conditions for nucleation and growth such that a number of resultant single crystalline nanowires are independently and uniformly aligned in a specific direction without aggregation thereof while having vertical and/or horizontal orientation to the surface of the substrate.

A long axis of the noble metal single crystalline nanowire prepared by nucleation and growth thereof on the substrate is substantially vertical or horizontal orientation to the surface of the substrate. Such a vertical or horizontal orientation may be controlled by kinds of the precursor, types of the single crystalline substrate, surface direction of the single crystalline substrate, conditions for heat treatment, flow rate of the inert gas, pressure, and/or combinations of two or more thereof.

More particularly, regulating temperature of a front part (on which the precursor is placed) and/or a rear part (on which the single crystalline substrate is placed) of a reaction furnace, as well as adjusting the flow rate of the inert gas and/or internal pressure of a heating tube may control a surface phase and a surface energy of the resultant noble metal single crystals. Finally, varying nucleation activation energy, growth activation energy, nucleation velocity and/or growth velocity of a noble metal on the single crystalline substrate may result in nucleation and growth of a noble metal, which in turn, prepares a noble metal nanowire with a specific orientation to the single crystalline substrate.

Herein, the substrate comprises a semiconductor or nonconductive single crystalline face on which nucleation, especially, two-dimensional nucleation of the resultant noble metal crystals is easily attained, and therefore, the substrate is preferably selected to cause neither elastic stress (or elastic strain) nor dislocation due to lattice mismatch.

Easy 2-dimensional nucleation of noble metal single crystals is determined by raw materials of a noble metal single crystalline nanowire to be desired, atomic structure of low ordered faces of the nanowires to be desired, raw materials or surface direction of the single crystalline substrate, or combinations of two or more thereof.

If using the same raw material of the noble metal single crystalline nanowire, nucleation and growth of the nanowire depend on raw materials or surface direction of the single crystalline substrate, or a combination thereof, thereby controlling orientations of the substrate and the noble metal single crystalline nanowire.

As described above, a semiconductor or nonconductive single crystalline substrate is not particularly restricted as long as it enables easy nucleation of a noble metal single crystalline nanowire and exhibits chemical/thermal stability under conditions for heat treatment disclosed above. However, the substrate may preferably include: a Group 4 element single crystalline substrate selected from silicon, germanium and silicon-germanium single crystalline substrates; a Group 3-5 element single crystalline substrate selected from gallium-arsenic, indium-phosphorous and gallium-phosphorous single crystalline substrates; a Group 2-6 element single crystalline substrate; a Group 4-6 element single crystalline substrate; a sapphire single crystalline substrate; a silicon oxide single crystalline substrate; and a laminate of two or more thereof.

For example, when the noble metal single crystalline nanowire is an Au or Pd single crystalline nanowire, the substrate is preferably a sapphire single crystalline substrate that is commercially available with economical price and enables easy nucleation of noble metal on a low ordered surface with thermodynamic stability.

As described above, in order to prepare a noble metal nanowire with orientation to the surface of the single crystalline substrate, there may be a requirement for controlling the initial nucleation and growth step of the noble metal. Conditions for this process may include internal pressure of a heating tube, heating temperature at a front part (containing the precursor) and a rear part (containing the substrate) of a reaction furnace, flow rate of inert gas, and so forth.

From theoretical and/or experimental results, it is well known that each material having crystalline properties exhibits singular-rough phase transformation wherein an atomic structure of a surface of the material is altered by temperature, pressure, atmosphere, impurities and the like influencing surface energy. One of the most effective factors for the phase transformation is temperature. A single crystal which is thermodynamically stable at high temperatures may have a rounded shape without angles, wherein atoms on the surface of the material exhibit an atomically rough structure. If the temperature is lowered, influence of broken bond energy increases according to a direction of single crystals rather than entropy energy, thus generating faceted shapes. Each face of the single crystal with a faceted shape is a face in the direction of single crystals having small surface energy wherein the surface of the material exhibits an atomically flat (or singular) structure.

Such a thermodynamic surface phase transformation has significant influence on nucleation and growth of particles. When the surface of a material has an atomically rough structure, it induces a typical nucleation and growth of particles. However, when the surface shows an atomically singular structure, 2-D nucleation and lateral growth of particles occur.

A method for preparation of a noble metal nanowire with specific orientation to a surface of a single crystalline substrate according to the present invention comprises regulating heat treatment temperature and/or pressure to control a thermodynamically stable surface phase of a noble metal, and altering flow rate of inert gas to control nucleation and growth driving effects on the surface of the substrate, thereby obtaining a specific orientation in alignment.

In order to attain such nucleation and growth conditions, a precursor is preferably maintained at 1,000 to 1,200° C. while maintaining a single crystalline substrate at 800 to 1,100° C. The heat treatment is preferably performed under a pressure of 3 to 20 torr while inert gas flows at a flow rate of 50 to 200 sccm from a front part (on which the precursor is placed) to a rear part (on which the substrate is placed) of a reaction furnace.

Out of the preferable ranges of temperature, pressure and/or flow rate of the inert gas, the noble metal nanowire may lose orientation to the surface of the substrate, there may be grown noble metals in the form of a rod or particle rather than the form of a nanowire, and/or the prepared nanowire may become polycrystalline instead of single crystalline in structure.

In order to prepare a noble metal nanowire aligned with vertical orientation to a surface of the single crystalline substrate, a precursor is preferably maintained at 1,000 to 1,200° C. while maintaining the single crystalline substrate at 850 to 1,100° C. The heat treatment is preferably performed under a pressure of 3 to 8 torr while inert gas flows at a flow rate of 50 to 200 sccm from a front part (on which the precursor is placed) to a rear part (on which the substrate is placed) of a reaction furnace.

On the other hand, in order to prepare a noble metal nanowire aligned with horizontal orientation to a surface of a single crystalline substrate, a precursor is preferably maintained at 1,000 to 1,200° C. while maintaining the single crystalline substrate at 800 to 950° C. The heat treatment is preferably performed under a pressure of 15 to 20 torr while inert gas flows at a flow rate of 50 to 200 sccm from a front part (on which the precursor is placed) to a rear part (on which the substrate is placed) of a reaction furnace.

A heating time must be optimized according to conditions for the heat treatment including temperature, flow rate of inert gas and/or pressure. Preferably, the heating time ranges from 30 minutes to 2 hours. During the heat treatment process, the precursor vaporized by the inert gas moves to the single crystalline substrate to participate nucleation and growth. At the same time, a material transfer may occur between noble metals formed on the substrate via vapor phase and/or the surface of the substrate, resulting in particle growth.

Accordingly, after the heat treatment, the single crystalline substrate on which the noble metal nanowire was prepared is subjected to removal of the precursor and further heat treatment so that the nanowire has orientation to the surface of the single crystalline substrate and/or density or size of the aligned nanowire may be controlled.

The precursor usable in the method of the present invention may include noble metal oxides, noble metals or noble metal halides and using at least one of these materials may produce a noble metal single crystalline nanowire. The noble metal oxide may include gold oxide, silver oxide, palladium oxide, platinum oxide, iridium oxide, osmium oxide, rhodium oxide, ruthenium oxide and the like. Using this noble metal oxide may prepare an Au, Ag, Pd, Pt, Ir, Os, Rh or Ru single crystalline nanowire. The noble metal may include Au, Ag, Pd, Pt, Ir, Os, Rh, Ru and the like. The noble metal halide may be selected from noble metal fluoride, noble metal chloride, noble metal bromide and noble metal iodide, preferably noble metal chloride, noble metal bromide or noble metal iodide, and more preferably noble metal chloride. Such noble metal halide may have at least one noble metal selected from Au, Ag, Pd, Pt, Ir, Os, Rh and Ru. The noble metal halide may further include a hydrated noble metal halide.

The precursor is preferably a noble metal oxide or noble metal.

In order to control magnetic properties of the noble metal nanowire, the precursor may further include transition metal materials, which may include Co, Fe, Mg, Mn, Cr, Zr, Cu, Zn, V, Ti, Nb, Y or combinations of two or more thereof.

Using Au₂O₃, Au or gold halide, and preferably Au₂O₃ or Au as the precursor may prepare Au single crystalline nanowire aligned with orientation to the surface of the single crystalline substrate. Using PdO, Pd or palladium halide, and preferably PdO or Pd as the precursor may prepare Pd single crystalline nanowire aligned with orientation to the surface of the single crystalline substrate.

The gold halide may be selected from a group consisting of gold fluoride, gold chloride, gold bromide and gold iodide, while the palladium halide may be selected from a group consisting of palladium fluoride, palladium chloride, palladium bromide and palladium iodide.

As for experimental demonstration for improvement of the method of the present invention, using Au₂O₃, PdO, Au and Pd as each precursor according to the present invention, respectively, an Au single crystalline nanowire and Pd single crystalline nanowire with orientation to a substrate, respectively, were prepared (as described in Examples 1 to 5).

### Example 1

An Au single crystalline nanowire vertically oriented to a substrate was prepared by a vapor phase transport method in a reaction furnace.

The reaction furnace had a front part and a rear part, and was equipped with an independent heating element and a thermostat. A quartz tube having a diameter of 1 inch and a length of 60 cm was mounted within the reaction furnace.

A boat type container made of high purity alumina material putting 0.02 g of Au₂O₃ (Sigma-Aldrich, 334057) as a precursor was placed on the center of the front part of the reaction furnace, while a sapphire single crystalline substrate having a surface (0001) was located in the center of the rear part of the reaction furnace. Argon (Ar) gas was introduced into the front part and discharged out of the rear part. At the rear part, a vacuum pump is fixed. Using the vacuum pump, the internal pressure of the quartz tube was maintained at 5 torr while flowing Ar gas at a flow rate of 100 sccm using a mass flow control (MFC) device.

Heat treatment was performed over 30 minutes while maintaining the front part (on which the alumina boat putting the precursor was placed) at 1,100° C. and the rear part (on which the silicon substrate was placed) at 900° C.

### Example 2

A Pd single crystalline nanowire vertically oriented to a substrate was prepared by a vapor phase transport method in a reaction furnace.

The Pd nanowire was prepared using the same apparatus under the same conditions as described in Example 1, except heating temperature, kinds of the precursor, flow rate of the inert gas and pressure.

0.05 g of PdO (Sigma-Aldrich, 203971) was used as the precursor and the internal pressure of the quartz tube was maintained at 6 torr using the vacuum pump.

Heat treatment was performed over 30 minutes under Ar gas at a flow rate of 140 sccm, while maintaining the front part (on which the alumina boat putting the precursor was placed) at 1,100° C. and the rear part (on which the silicon substrate was placed) at 900° C. As a result, the Pd single crystalline nanowire was prepared.

### Example 3

An Au single crystalline nanowire horizontally oriented to a substrate was prepared by a vapor phase transport method in a reaction furnace.

The Au nanowire was prepared using the same apparatus under the same conditions as described in Example 1, except heating temperature, pressure and flow rate of the inert gas.

The internal pressure of the quartz tube was maintained at 17 torr using the vacuum pump.

Heat treatment was performed over 30 minutes under Ar gas at a flow rate of 80 sccm, while maintaining the front part (on which the alumina boat putting the precursor was placed) at 1,100° C. and the rear part (on which the silicon substrate was placed) at 850° C. As a result, the Au single crystalline nanowire was prepared.

### Example 4

An Au single crystalline nanowire horizontally oriented to a substrate was prepared by a vapor phase transport method in a reaction furnace.

The Au nanowire was prepared using the same apparatus under the same conditions as described in Example 3, except that a sapphire single crystalline substrate having a face (11-20) was used.

### Example 5

A Pd single crystalline nanowire horizontally oriented to a substrate was prepared by a vapor phase transport method in a reaction furnace.

The Pd nanowire was prepared using the same apparatus under the same conditions as described in Example 2, except heating temperature, pressure and flow rate of the inert gas.

The internal pressure of the quartz tube was maintained at 20 torr using the vacuum pump. Heat treatment was performed over 30 minutes under Ar gas at a flow rate of 100 sccm, while maintaining the front part (on which the alumina boat putting the precursor was placed) at 1,100° C. and the rear part (on which the silicon substrate was placed) at 850° C. As a result, the Pd single crystalline nanowire was prepared.

### Example 6

An Au single crystalline nanowire vertically oriented to a substrate was prepared using an Au precursor.

The Au nanowire was prepared under the same conditions as described in Example 1, except that 0.02 g of Au was used as the precursor.

### Example 7

A Pd single crystalline nanowire vertically oriented to a substrate was prepared using a Pd precursor.

The Pd nanowire was prepared under the same conditions as described in Example 2, except that 0.05 g of Pd was used as the precursor.

### Example 8

An Au single crystalline nanowire horizontally oriented to a substrate was prepared using an Au precursor.

The Au nanowire was prepared under the same conditions as described in Example 3, except that Au was used as the precursor.

### Example 9

A Pd single crystalline nanowire horizontally oriented to a substrate was prepared using a Pd precursor.

The Pd nanowire was prepared under the same conditions as described in Example 5, except that Pd was used as the precursor.

The nanowire prepared in Example 1 has substantially the same physical properties as the nanowire prepared in Example 6. Likewise, the nanowire prepared in Example 2 has substantially the same physical properties as the nanowire prepared in Example 7, while the nanowire prepared in Example 3 has substantially the same physical properties as the nanowire prepared in Example 8. In addition, the nanowire prepared in Example 5 has substantially the same physical properties as the nanowire prepared in Example 9. Therefore, a detailed description will be given of characteristics of the prepared single crystalline nanowire according to the present invention, with reference to Examples 1 to 5.

Analysis of each noble metal single crystalline nanowire prepared in Examples 1 to 5 was performed in terms of quality, shape and purity of the nanowire having orientation to the substrate.

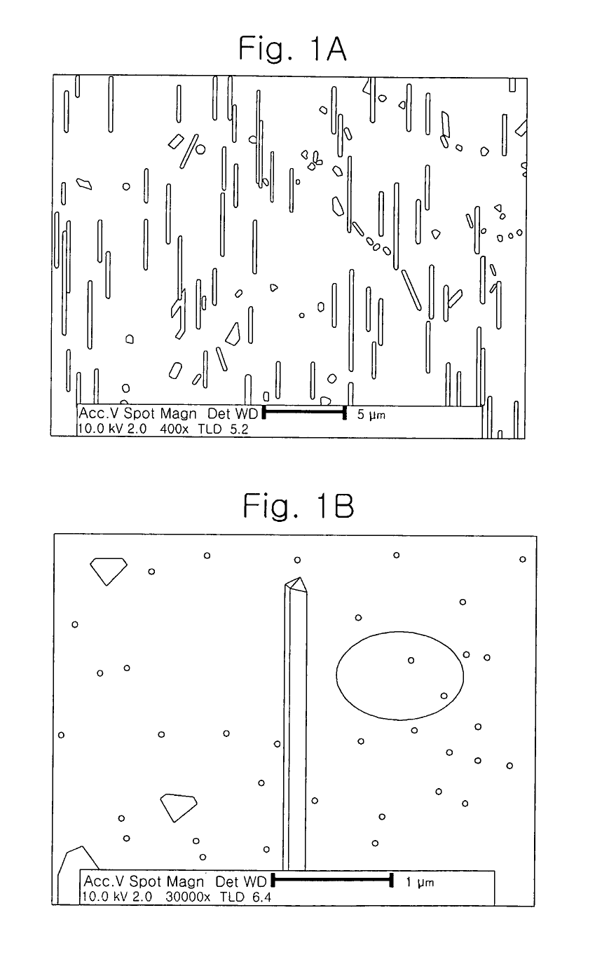

FIGS. 1A to 4 illustrate measured results from the Au single crystalline nanowire prepared in Example 1. FIG. 1A is a SEM picture showing the Au single crystalline nanowire grown on a sapphire single crystalline substrate. As shown in FIG. 1A, the Au single crystalline nanowire of the present invention was aligned and grown in a direction vertical to a surface of the single crystalline substrate. Also, the picture showed that a number of single crystalline nanowires were prepared. The nanowires had a linear form extending in a long axis and were individually separable without aggregation thereof. HRSEM in FIG. 1B showed that the Au single crystalline nanowire had a macroscopically faceted shape.

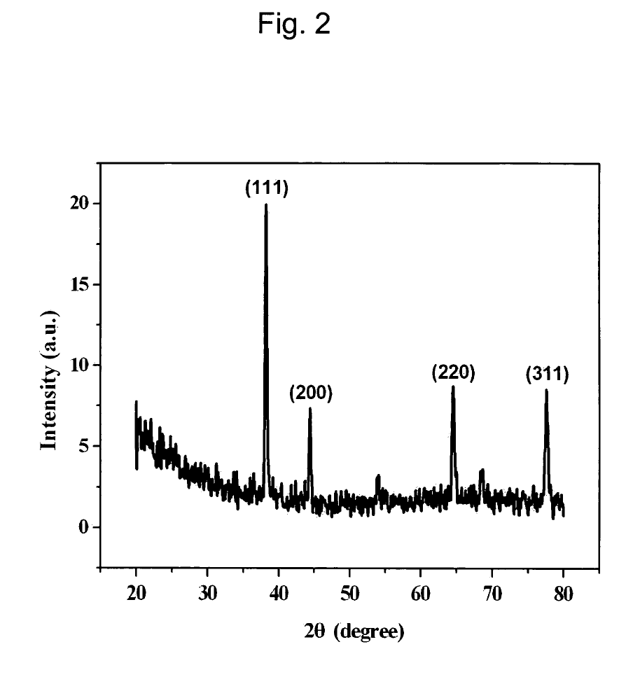

FIG. 2 is a graphical representation illustrating an XRD result of the Au single crystalline nanowire. The XRD result was substantially identical to an Au diffraction result of Bulk Au without peak shift of a diffraction peak and, from the result, it can be seen that the prepared Au single crystalline nanowire had a face centered cubic (FCC) structure.

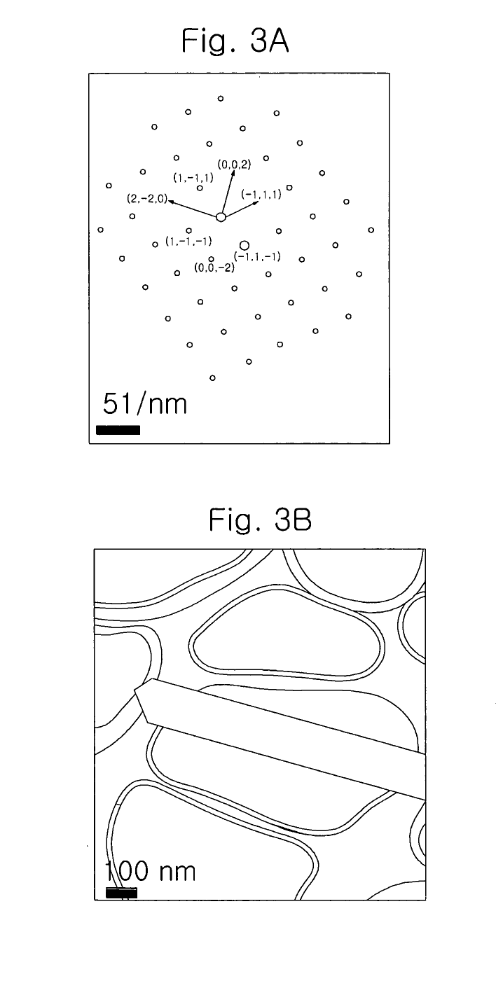

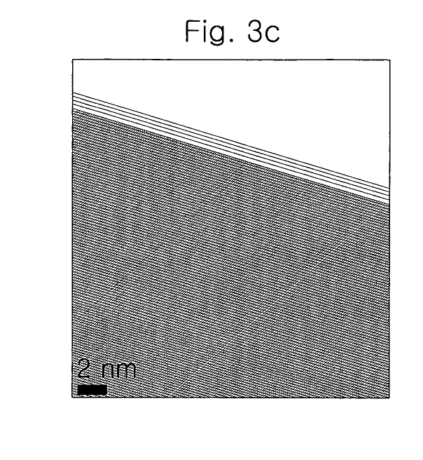

The structure and shape of the prepared Au single crystalline nanowire were observed in detail by TEM. From results shown in FIGS. 3A to 3C, it can be seen that the prepared Au single crystalline nanowire had a smooth surface as well as the faceted shape. From a selected area electron diffraction (SAED) pattern shown in FIG. 3A, it can be seen that the Au single crystalline nanowire was a single crystalline material substantially comprising a single crystal. FIG. 3A and FIG. 3B demonstrated that the growth direction of the Au single crystalline nanowire was <110>, while FIG. 3C showed that the nanowire was a complete single crystal.

From results shown in FIG. 1A to FIG. 3C, a cross-section vertical to the growth direction of the Au single crystalline nanowire had a faceted shape with a tangential gradient to an outer circumference of the cross-section, which was discontinuously varied. The faceted surface of the nanowire comprised each face such as low ordered faces {111},{110},{100}, etc.

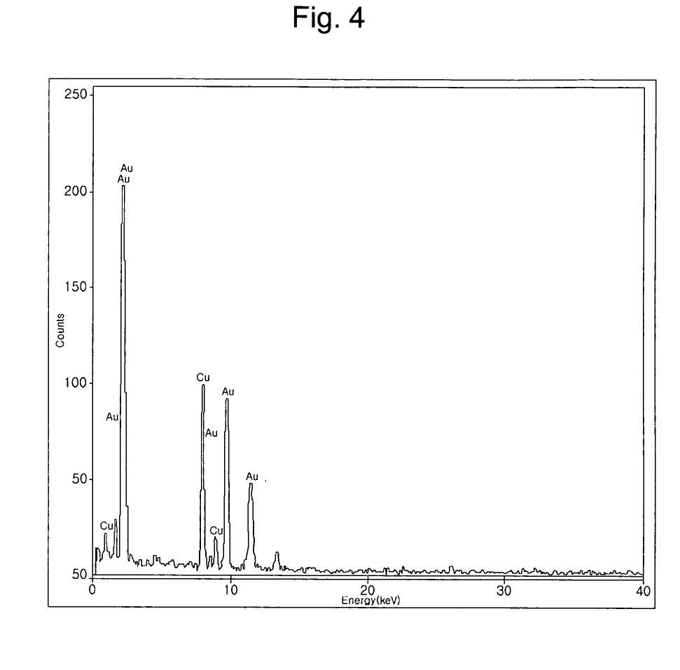

FIG. 4 is a graphical representation illustrating an analysis result of ingredients in the Au single-crystalline nanowire by an apparatus using energy dispersive spectroscopy (EDS) mounted on TEM equipment. From the result shown in FIG. 4, it can be seen that the nanowire comprised only Au except other materials such as a grid additionally measured owing to features of the measurement equipment.

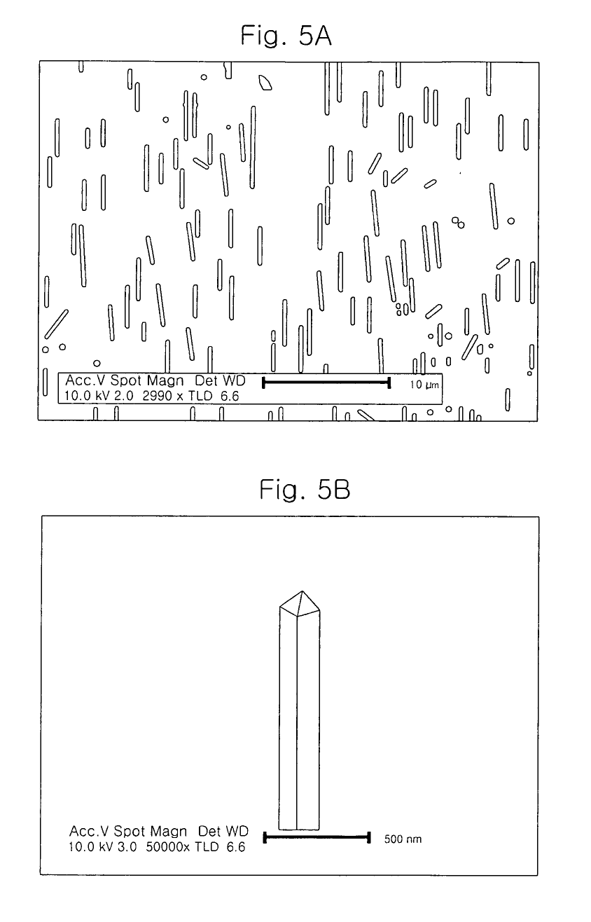

FIGS. 5A to 8 illustrate measured results from the Pd single crystalline nanowire prepared in Example 2.

FIG. 5A is a SEM picture showing the Au single crystalline nanowire grown on a sapphire single crystalline substrate. It was found that a number of nanowires having a diameter of 50 to 150 nm and a length of 5 to 10 μm were aligned and grown in a direction vertical to a surface of the single crystalline substrate. The nanowires had a linear form extending in a long axis and were individually separable without aggregation thereof. HRSEM in FIG. 5(b) showed that the Pd single crystalline nanowire had a macroscopically faceted shape.

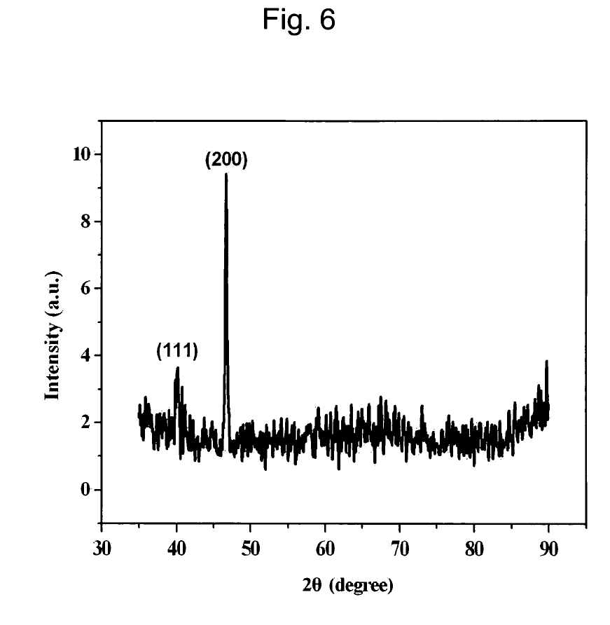

FIG. 6 is a graphical representation illustrating an XRD result of the Pd single crystalline nanowire. The XRD result of the prepared Pd single crystalline nanowire was substantially identical to a Pd diffraction result of bulk Pd and, from the result, it can be seen that the prepared nanowire had an FCC structure.

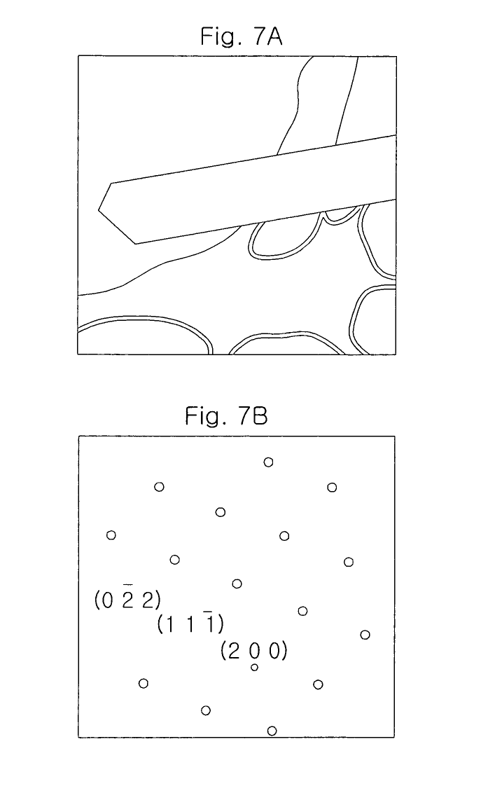

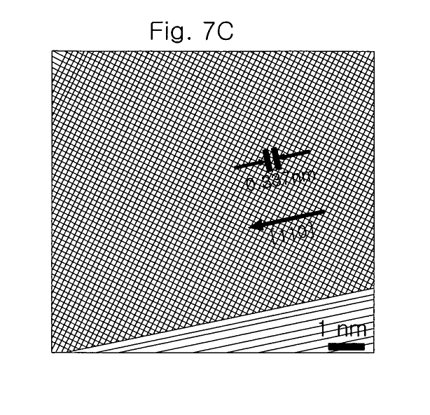

The structure and shape of the prepared Pd single crystalline nanowire were observed in detail by TEM. From results shown in FIGS. 7A to 7C, it can be seen that the prepared Pd single crystalline nanowire had a smooth surface as well as the faceted shape. From a SAED pattern shown in FIG. 7A, it can be seen that the Pd single crystalline nanowire was a single crystalline material substantially comprising a single crystal and the growth direction (long axis) of the Pd single crystalline nanowire was <110>. The faceted surface of the nanowire comprised each face such as low ordered faces {111},{110},{100}, etc. In addition, HRTEM image in FIG. 7C demonstrated that the prepared single crystalline nanowire exhibited high crystalline quality without defects.

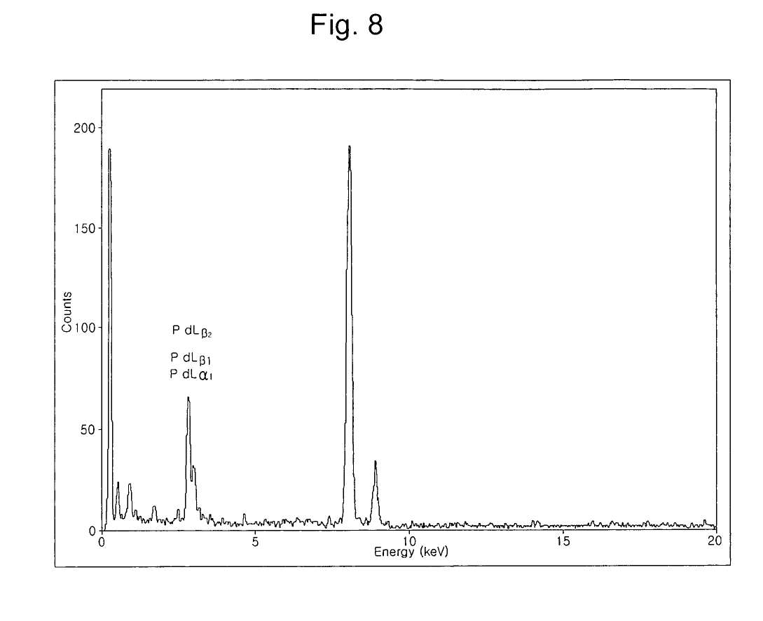

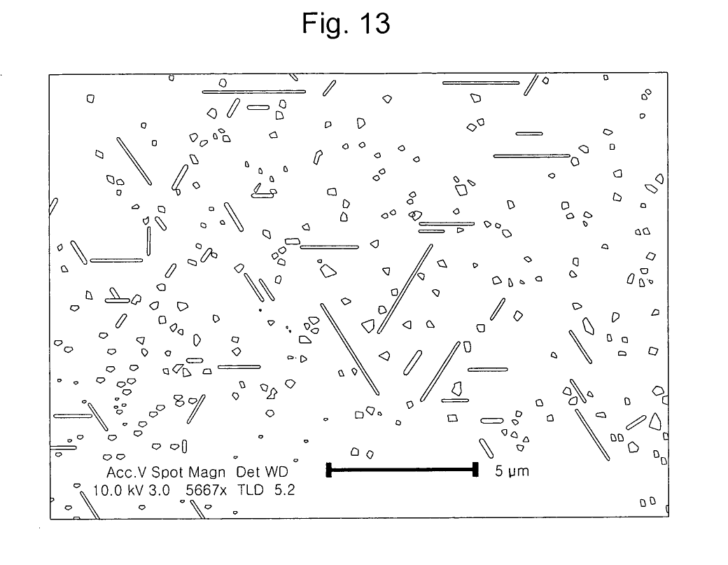

FIG. 8 is a graphical representation illustrating an analysis result of ingredients in the Pd single-crystalline nanowire by an apparatus using EDS mounted on TEM equipment. FIG. 13 is a SEM picture showing the Pd single crystalline nanowire. From the results shown in FIGS. 8 and 13, it can be seen that the nanowire comprised only Pd except other materials such as a grid additionally measured owing to features of the measurement equipment.

As is apparent from the above description, analysis results of each noble metal nanowire prepared in Examples 1 and 2 demonstrated that the noble metal nanowire of the present invention is commonly aligned and grown in a direction vertical to a surface of the single crystalline substrate, is grown into a high quality single crystal and becomes a high purity nanowire without impurities, regardless of raw materials thereof. Additionally, a number of nanowires are prepared on the substrate and are not aggregated with one another but individually separable. In the aspect of crystallographic characteristics, it can be identified that the noble metal single crystalline nanowire of the present invention has substantially the same crystal structure as bulk noble metal and the single crystalline nanowire has a growth direction (long axis) of <100> and a faceted shape.

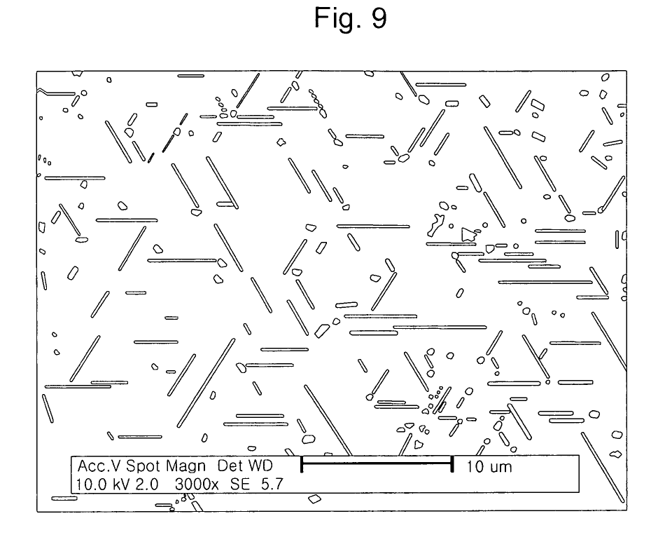

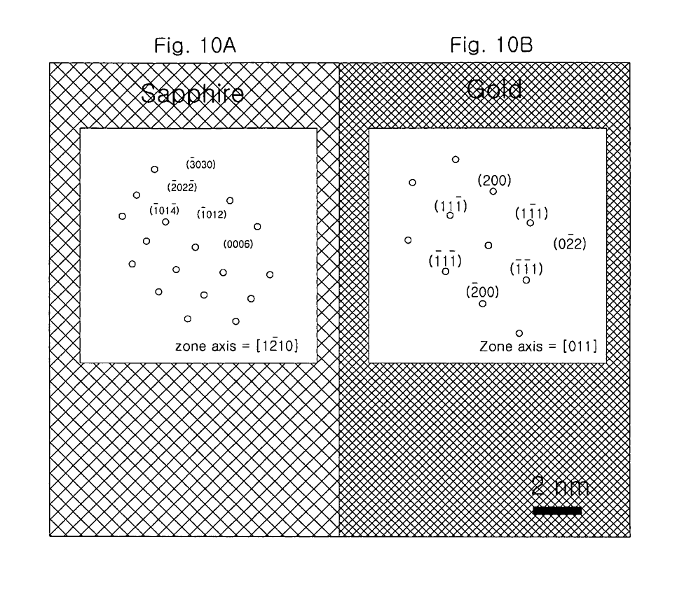

FIGS. 9, 10A and 10B illustrate measured results from the Au single crystalline nanowire prepared in Example 3.

FIG. 9 is a SEM picture showing the Au single crystalline nanowire grown on a sapphire single crystalline substrate. As shown in FIG. 9, a number of nanowires were aligned and grown in a direction horizontal to a surface of the single crystalline substrate.

FIGS. 10A and 10B are an HRTEM picture showing a barrier between the Au single crystalline nanowire and a sapphire substrate. From an electron diffraction pattern shown in FIG. 10B, it can be seen that the Au single crystalline nanowire comprised a pure single crystal and had an FCC structure identical to that of an Bulk Au. In addition, a crystallographic relation between the Au single crystalline nanowire and the substrate was observed in detail by TEM. FIGS. 10A and 10B demonstrated that the face (110) of the Au single crystalline nanowire is epitaxial to the surface (0001) of the sapphire single crystalline substrate.

That is, it was found that the Au single crystalline nanowire epitaxially grown on the surface of the sapphire single crystalline substrate has a growth direction <110>, and the long axis <110> of the Au nanowire is parallel to a direction of the surface <11-20> of the sapphire single crystalline substrate. Consequently, it can be seen that a number of Au single crystalline nanowires horizontally grown as shown in FIG. 9 were aligned in a triangular or hexagonal shape in six (6) directions, which are substantially the same as the surface <11-20> in view of crystallographic features.

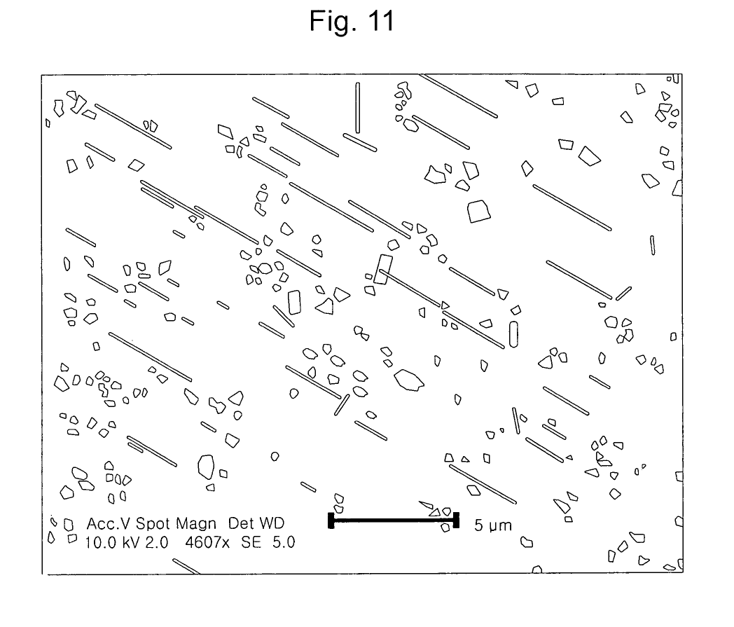

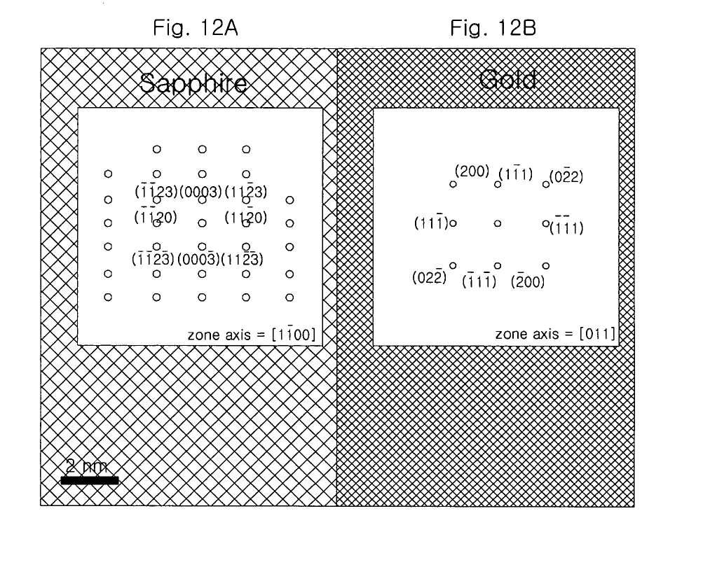

FIGS. 11, 12A and 12B illustrate measured results from the Au single crystalline nanowire prepared in Example 4.

FIG. 11 is a SEM picture showing the Au single crystalline nanowire formed on a sapphire single crystalline substrate at “a” face. Similar to Example 3, a number of nanowires were aligned and grown in a direction horizontal to a surface of the single crystalline substrate. However, compared to Example 3 describing that the long axis <110> of the Au single crystalline nanowire is aligned in the six (6) directions which are substantially the same as the surface <11-20> of the single crystalline substrate in view of crystallographic features, Example 4 described the Au single crystalline nanowire with a single alignment direction.

FIGS. 12A and 12B are an HRTEM picture showing a barrier between the Au single crystalline nanowire and the sapphire substrate. From an electron diffraction pattern shown in FIG. 12B, it can be seen that the Au single crystalline nanowire comprised a pure single crystal and had an FCC structure identical to that of the Bulk Au. In addition, a crystallographic relation between the Au single crystalline nanowire and the substrate was observed in detail by TEM. The results observed were substantially identical to those of Example 3 and demonstrated that the Au single crystalline nanowire has the growth direction <110>. From the same results, it can be seen that a face (11-1) of the prepared Au single crystalline nanowire is epitaxial to a surface (11-20) of the sapphire single crystalline substrate, and also, the long axial direction <110> of the Au single crystalline nanowire is parallel to a direction <0001> of the sapphire single crystalline substrate at “a” face. Therefore, it can be understood that a number of Au single crystalline nanowires horizontally grown as shown in FIG. 11 are aligned in a single direction <0001>.

Each Au single crystalline nanowire prepared in Examples 3 and 4, respectively, was subjected to analysis of ingredients by an apparatus using EDS mounted on TEM equipment. Similar to Example 3, it can be seen that the Au single crystalline nanowire comprised only pure Au except other materials such as a grid additionally measured owing to features of the measurement equipment.

FIG. 13 is a SEM picture showing a Pd single crystalline nanowire prepared according to Example 5 of the present invention. Similar to the Au single crystalline nanowire grown parallel to the substrate as described in Examples 3 and 4, Example 5 described the Pd single crystalline nanowire grown parallel to the substrate. From analysis results of a crystal structure of the nanowire observed by TEM, it can be seen that a Pd nanowire was prepared by the same procedure in Example 2. Analysis results of ingredients of the nanowire by the EDS mounted on the TEM equipment demonstrated that the Pd nanowire comprised only pure Pd.

The above examples 1 to 5 described in detail that a high purity and quality noble metal nanowire which is a pure single crystalline material, has reduced defects and a specific orientation may be prepared using a precursor including a noble metal oxide, noble metal or noble metal halide under non-catalyst conditions. Such an orientation may be controlled by kinds of the precursor, types of a single crystalline substrate, surface direction of the single crystalline substrate, heating temperature, flow rate of inert gas, pressure and/or combinations of two or more thereof.

A method for preparation of a noble metal nanowire and the noble metal nanowire prepared by the same according to the present invention may enable orientation to a surface of the substrate as well as size and/or shape of the nanowire to be preferably controlled. The method of the present invention is reproducible and allows mass-production of high purity and quality nanowires through a simple production process, thus affording an opportunity for studies in regard to physical, optical and/or electro-magnetic properties of noble metal nanowires. Using a noble metal nanowire made of any specific noble metal with excellent electric conductivity and thermal conductivity as well as chemical stability may improve characteristics of an electric device, an optical device or a magnetic device while reducing a size thereof. Especially, applying the noble metal nanowire to spectrometric equipment, bio-sensors, or other sensors used to detect light, electric or magnetic energy, heat, vibration and/or combinations of two or more thereof may control detectible characteristics and improve sensitivity, precision and/or reproducibility of the sensors. In addition, a vertical alignment property of the nanowire to the surface of the single crystalline substrate may be preferably applied to manufacture of a MEMS structure, a three-dimensional memory device, and so forth.

As is apparent from the above disclosure, exemplary embodiments of the present invention including, for example, specific precursors, single crystalline substrate and the like have been described in detail with reference to the above examples and drawings, which are one given for the purpose of illustration. Therefore, those skilled in the art will appreciate that various modifications, additions and/or variations are possible without departing from the principles and spirit of the invention, the scope of which is defined in the claims and their equivalents.

What is claimed is:

1. A noble metal single crystalline nanowire with orientation to a surface of a semiconductor or nonconductive single crystalline substrate, prepared using a precursor containing a noble metal oxide, noble metal or noble metal halide under non-catalyst conditions.

2. The nanowire according to claim 1,
wherein the orientation is vertical or horizontal orientation.

3. The nanowire according to claim 1,
wherein the noble metal oxide is selected from gold oxide (Au₂O₃) or palladium oxide (PdO), the noble metal is selected from gold(Au) or palladium(Pd), and the noble metal halide is selected from gold halide or palladium halide.

4. The nanowire according to claim 2,
wherein the noble metal crystalline nanowire is grown in a direction vertical to the surface of the single crystalline substrate.

5. The nanowire according to claim 4,
wherein the precursor is Au₂O₃ or Au, and the vertically grown noble metal single crystalline nanowire is an Au single crystalline nanowire.

6. The nanowire according to claim 5,
wherein the Au single crystalline nanowire has a face centered cubic structure and a long axial direction <110>.

7. The nanowire according to claim 4,
wherein the precursor is PdO or Pd, and the vertically grown noble metal single crystalline nanowire is a Pd single crystalline nanowire.

8. The nanowire according to claim 7,
wherein the Pd single crystalline nanowire has a face centered cubic structure and a long axial direction <110>.

9. The nanowire according to claim 4,
wherein the noble metal single crystalline nanowire has the same crystalline structure as bulk noble metal and a faceted shape.

10. The nanowire according to claim 4,
wherein the precursor is maintained at 1,000 to 1,200° C., the single crystalline substrate is maintained at 850 to 1,100° C., and inert gas flows from a front part of a reaction furnace to a rear part of the same at a flow rate of 50 to 200 sccm under a pressure of 3 to 8 torr so that the noble metal single crystalline nanowire is grown in a direction vertical to the surface of the single crystalline substrate.

11. The nanowire according to claim 2,
wherein the noble metal crystalline nanowire is horizontally grown in a direction parallel to the surface of the single crystalline substrate.

12. The nanowire according to claim 11,
wherein the precursor is Au₂O₃ or Au, and the noble metal single crystalline nanowire horizontally grown in a direction parallel to the surface of the single crystalline substrate is an Au single crystalline nanowire.

13. The nanowire according to claim 12,
wherein the single crystalline substrate is a sapphire substrate with a surface {0001}, and the surface {0001} is substantially parallel to a face centered cubic structural face {110} of the Au single crystalline nanowire.

14. The nanowire according to claim 12,
wherein the single crystalline substrate is a sapphire substrate with a surface (11-20), and the surface {11-20} is substantially parallel to a face centered cubic structural face (111) of the Au single crystalline nanowire.

15. The nanowire according to claim 11,
wherein the precursor is PdO or Pd, and the noble metal single crystalline nanowire horizontally grown in a direction parallel to the surface of the single crystalline substrate is a Pd single crystalline nanowire.

16. The nanowire according to claim 15,
wherein the Pd single crystalline nanowire has a face centered cubic structure.

17. The nanowire according to claim 15,
wherein the single crystalline substrate is a sapphire substrate with a surface {0001}.

18. The nanowire according to claim 11,
wherein the precursor is maintained at 1,000 to 1,200° C., the single crystalline substrate is maintained at 800 to 950° C., and inert gas flows from a front part of a reaction furnace to a rear part of the same at a flow rate of 50 to 200 sccm under a pressure of 15 to 20 torr so that the noble metal single crystalline nanowire is grown in a direction vertical to the surface of the single crystalline substrate.

19. The nanowire according to claim 1,
wherein the single crystalline substrate is a sapphire single crystalline substrate.

20. A method for preparation of a noble metal single crystalline nanowire comprising:
heat treating a precursor containing a noble metal oxide, noble metal or noble metal halide, which is placed in a front part of a reaction furnace, and a semiconductor or nonconductive single crystalline substrate placed in a rear part of the reaction furnace at a certain pressure in inert gas atmosphere, so as to produce a noble metal single crystalline nanowire oriented to a surface of the single crystalline substrate.

21. The method according to claim 20,
wherein a long axis of the noble metal single crystalline nanowire is oriented in a vertical or horizontal orientation to the surface of the single crystalline substrate.

22. The method according to claim 20,
wherein the orientation is controlled by kinds of the precursor, types of the single crystalline substrate, directions of the surface of the single crystalline substrate, conditions for the heat treatment, flow rate of the inert gas, pressure, and/or combinations of two or more thereof.

23. The method according to claim 20,
wherein the noble metal single crystalline nanowire is grown in a direction vertical to the surface of the single crystalline substrate.

24. The method according to claim 23,
wherein the precursor is maintained at 1,000 to 1,200° C., and the single crystalline substrate is maintained at 850 to 1,100° C.

25. The method according to claim 24,
wherein the inert gas flows from the front part of the reaction furnace to the rear part of the same at a flow rate of 50 to 200 sccm.

26. The method according to claim 25,
wherein the heat treatment is performed under a pressure of 3 to 8 torr.

27. The method according to claim 20,
wherein the noble metal single crystalline nanowire is horizontally grown in a direction parallel to the surface of the single crystalline substrate.

28. The method according to claim 27,
wherein the precursor is maintained at 1,000 to 1,200° C., and the single crystalline substrate is maintained at 800 to 950° C.

29. The method according to claim 28,
wherein the inert gas flows from the front part of the reaction furnace to the rear part of the same at a flow rate of 50 to 200 sccm.

30. The method according to claim 29,
wherein the heat treatment is performed at a pressure of 15 to 20 torr.

31. The method according to claim 20,
wherein the noble metal oxide is selected from Au₂O₃ or PdO, the noble metal is selected from Au or Pd, and the noble metal halide is selected from gold halide or palladium halide.

32. The method according to claim 20,
wherein the single crystalline substrate is at least one selected from a group consisting of a Group 4 element single crystalline substrate, a Group 3-5 element single crystalline substrate, a Group 2-6 element single crystalline substrate, a Group 4-6 element single crystalline substrate, a sapphire single crystalline substrate, a silicon oxide single crystalline substrate, and a laminate of two or more thereof.

33. A device selected from a group consisting of an electric device, an optical device, a magnetic device, a memory device and a device with a micro-electro-mechanical systems (MEMS) structure, which has a noble metal single crystalline nanowire prepared by the method as set forth in claim 20.

34. A device selected from a group consisting of an electric device, an optical device, a magnetic device, a memory device and a device with a MEMS structure, which has the noble metal single crystalline nanowire as set forth in claim 1.
